(19) United States
(12) Patent Application Publication
(10) Pub. No.: US 2016/0005736 A1
(43) Pub. Date: Jan. 7, 2016

(54) INGAAS FINFET ON PATTERNED SILICON SUBSTRATE WITH INP AS A BUFFER LAYER

(71) Applicant: Semiconductor Manufacturing International (Shanghai) Corporation, Shanghai (CN)

(72) Inventor: DEYUAN XIAO, Shanghai (CN)

(21) Appl. No.: 14/656,590

(22) Filed: Mar. 12, 2015

(30) Foreign Application Priority Data
Jul. 2, 2014 (CN) 201410311783.5

(51) Int. Cl. H01L 27/088; H01L 21/02; H01L 29/201; H01L 21/308; H01L 21/266; H01L 21/265; H01L 29/06; H01L 21/306; H01L 21/8234; H01L 29/205

(52) U.S. Cl. CPC H01L 27/0886; H01L 21/823431; H01L 21/823412; H01L 21/02461; H01L 21/02546; H01L 29/201; H01L 29/205; H01L 21/266; H01L 21/26546; H01L 29/0657; H01L 21/30612; H01L 21/3081

(57) ABSTRACT

A method for manufacturing a semiconductor device includes providing a substrate having an array of cavities. Each of the cavities has a plurality of lateral sides, and each lateral side has a lateral direction matching a lateral crystal plane of the substrate. The method also includes forming a buffer layer on the substrate and filling the cavities, and forming a fin-type channel layer on the buffer layer. Because the independently grown crystals in the cavities have a lateral direction in line with the direction of the lateral crystal plane, the dislocation defect density is significantly reduced, thereby greatly improving the device performance.

### CROSS-REFERENCES TO RELATED APPLICATIONS

This application claims priority to Chinese patent application No. 201410311783.5, filed on Jul. 2, 2014, the content of which is incorporated herein by reference in its entirety.

### BACKGROUND OF THE INVENTION

The present invention relates to semiconductor devices, and more particularly to semiconductor devices having a non-planar InGaAs FinFET and methods for manufacturing the same.

As the size of semiconductor devices is continuingly scaled down, it is nearly impossible to simultaneously realize high operational speed and low power consumption of semiconductor devices. By integrating higher performance materials on a silicon substrate, for example, III-V transistor channels can provide higher carrier mobility and higher drive current, this hybrid integration of III-V semiconductor materials on a silicon substrate allows continuingly scaling down beyond the capabilities of pure silicon semiconductor devices.

Currently, experiments have been conducted by growing III-V compound materials such as indium gallium arsenide (InGaAs) on a silicon substrate, however, the mismatch of atomic lattices in different materials present a challenge.

It is well known that there is a large difference in the lattice constant between an epitaxially grown layer and a silicon substrate, high density threading dislocation is inherent in the epitaxially grown III-V layer on the silicon substrate is constant. Therefore, reducing the dislocation density is an important issue in producing group III-V transistors on a silicon substrate.

### BRIEF SUMMARY OF THE INVENTION

Embodiments of the present invention provide a method for manufacturing a semiconductor device which is capable of preventing or at least reducing threading dislocation of III-V compound materials on a semiconductor substrate.

According to an embodiment of the present invention, a method for manufacturing a semiconductor device includes providing a substrate having an array of cavities. Each of the cavities has a number of lateral sides, and each lateral side has a lateral direction being in line with the direction of the lateral crystal plane of the substrate. The method also includes forming an epitaxial buffer layer on the substrate and filling the cavities, and forming a fin-type channel layer on the buffer layer.

The method further includes forming a gate structure having a gate dielectric layer covering at least a portion of the fin-type channel layer, a gate electrode on the gate dielectric layer, and sidewall spacers on opposite sides of the gate electrode.

In an embodiment, the method also includes performing an ion implantation onto the fin-type channel layer using the gate structure as a mask to form source and drain growth regions.

In an embodiment, providing the substrate includes patterning the substrate and etching the substrate using a wet etching process to form the array of cavities.

In an embodiment, forming the fin-type channel layer includes epitaxially growing a channel material layer on the buffer layer, and patterning the channel material layer to form the fin-type channel layer.

In an embodiment, the substrate is a silicon substrate.

In an embodiment, the buffer layer is made of InP.

In an embodiment, the fin-type channel layer is made of InGaAs. In another embodiment, the fin-type channel layer is made of P—InGaAs.

In an embodiment, the source and drain growth regions are made of N+—InGaAs.

In an embodiment, the buffer layer has a thickness in the range between 10 nm and 500 nm. The fin-type channel layer has a thickness in the range between 10 nm and 500 nm.

Embodiments of the present invention also provide a semiconductor device, which includes a substrate providing a substrate having an array of cavities, each of the cavities having a plurality of faceted sides, each side having a lateral direction coinciding with a crystal lateral direction of the substrate, a buffer layer disposed on the substrate and filling the cavities, and a fin-type channel layer disposed on the buffer layer.

In accordance with the present invention, because the independently grown crystals have a lateral crystal surface, the dislocation defect density is significantly reduced, thereby greatly improving the device performance.

### BRIEF DESCRIPTION OF THE DRAWINGS

The accompanying drawings, which are incorporated in and constitute a part of the specification, illustrate embodiments of the present invention. The like reference labels in various drawings refer to the like elements.

FIG. 1 is a flow chart of a method for manufacturing a semiconductor device according to an embodiment of the present invention; and

FIG. 2 is a cross-sectional view of an array of cavities according to an embodiment of the present invention.

FIG. 3 is a cross-sectional view of an intermediate structure in the manufacturing process of a semiconductor device illustrating a patterned hard mask disposed on a substrate according to an embodiment of the present invention.

FIG. 4 is a cross-sectional view of an intermediate structure in the manufacturing process of a semiconductor device illustrating a cavity being formed in a substrate according to an embodiment of the present invention.

FIG. 5 is a cross-sectional view of an intermediate structure in the manufacturing process of a semiconductor device illustrating a cavity being formed in a substrate according to another embodiment of the present invention.

FIG. 6 is a cross-sectional view of an intermediate structure in the manufacturing process of a semiconductor device illustrating the hard mask being removed according to an embodiment of the present invention.

FIG. 7 is a cross-sectional view of an intermediate structure in the manufacturing process of a semiconductor device illustrating a buffer layer being formed on the substrate according to an embodiment of the present invention.

FIG. 8 is a cross-sectional view of an intermediate structure in the manufacturing process of a semiconductor device illustrating a channel material layer being formed on the buffer layer according to an embodiment of the present invention.

FIG. 9A is a cross-sectional view in the traverse direction of a fin-type channel layer according to an embodiment of the present invention. FIG. 9B is a cross-sectional view in the length direction that is perpendicular to the traverse direction of FIG. 9A.

FIG. 10A is a cross-sectional view in the traverse direction of an intermediate structure after formation of a gate dielectric layer according to an embodiment of the present invention. FIG. 10B is a cross-sectional view in the length direction that is perpendicular to the traverse direction of FIG. 10A.

FIG. 11A is a cross-sectional view in the traverse direction of an intermediate structure after deposition of a gate material layer according to an embodiment of the present invention. FIG. 11B is a cross-sectional view in the length direction of FIG. 11A.

FIG. 12A is a cross-sectional view in the traverse direction of an intermediate structure after formation of a gate electrode according to an embodiment of the present invention. FIG. 12B is a cross-sectional view in the length direction of FIG. 12A.

FIG. 13A is a cross-sectional view in the traverse direction of an intermediate structure after formation of sidewall spacers on opposite sides of the gate electrode according to an embodiment of the present invention. FIG. 13B is a cross-sectional view in the length direction of FIG. 13A.

FIG. 14A is a cross-sectional view in the traverse direction of an intermediate structure after formation of source and drain regions by ion implantation according to an embodiment of the present invention. FIG. 14B is a cross-sectional view in the length direction of FIG. 14A.

FIG. 15 is a cross-sectional view illustrating formation of source and drain electrodes on corresponding source and drain regions according to an embodiment of the present invention.

The following description, together with the accompanying drawings, will provide a better understanding of the nature and advantages of the claimed invention.

### DETAILED DESCRIPTION OF THE INVENTION

The present invention will be understood more fully from the detailed description given below and from the accompanying drawings of the preferred embodiments of the invention, which, however, should not be taken to limit the invention to the specific embodiments, but are for explanation and understanding only.

It should be understood that the drawings are not drawn to scale, and similar reference numbers are used for representing similar elements. Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

The present invention will now be described more fully herein after with reference to the accompanying drawings, in which preferred embodiments of the invention are shown. This invention may, however, be embodied in many different forms and should not be construed as limited by the embodiments set forth herein. Rather, these embodiments are provided so that this disclosure will be thorough and complete, and will fully convey the scope of the invention to those skilled in the art.

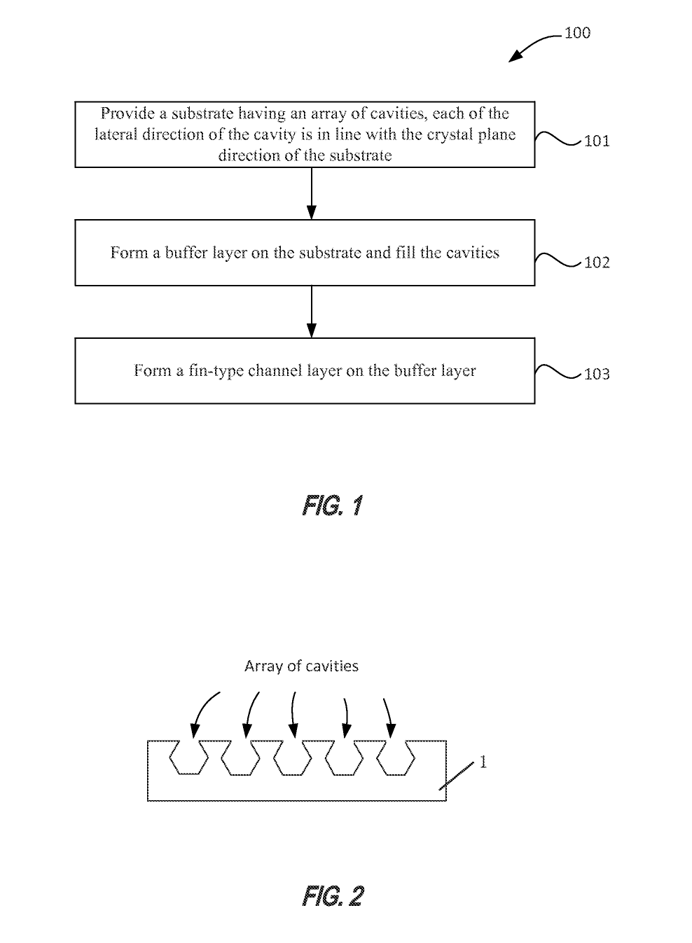

FIG. 1 is a flow chart of a method 100 for manufacturing a semiconductor device according to an embodiment of the present invention. Method 100 includes the following steps:

Step 101: providing a substrate, which has an array of cavities, each cavity has a number of lateral sides (planes), and each lateral side has a lateral direction that is in line with the direction of the lateral crystal plane of the substrate. The term “cavity” used herein may be understood as “trench”, “opening”, “groove”, “trough” that can have any shape or profile. For example, the cavity may have a polygonal shape having multiple lateral sides or planes. FIG. 2 shows a cross-sectional view of an array of cavities, each of the cavities has a hexagonal (sigma) shape, i.e., a Σ-shaped profile.

In an embodiment, providing the substrate may include patterning the substrate using a hard mask having an array of openings to form the array of cavities in the substrate, and performing an orientation selective wet etching the substrate to form the Σ-shaped cavities.

In some embodiments, the array of cavities may have a density in the range from 1 to 100 cavities/um².

In certain embodiments, the substrate is made of a silicon material.

Step 102: forming a buffer layer on the patterned substrate and filling the cavities.

In some embodiments, the buffer layer may be epitaxially grown within the cavities and overgrown over the boundaries of the cavities. In some embodiments, the epitaxial buffer layer is made of InP.

In some embodiments, the buffer layer has a thickness in the range from 10 to 500 nm.

It should be noted that, since the patterning of the substrate divides the substrate into a number of separated regions, the growth process of the migration of surface atoms is interrupted at the boundaries of the separated regions, therefore, InP can be independently grown in the regions, the InP growth has a horizontal component and a vertical component. In each region, the independently and epitaxially grown buffer layer has a lateral direction in line with the direction of the lateral crystal plane, thereby significantly reducing the dislocation defect density.

S103: forming a fin-type channel layer on the buffer layer.

In an embodiment, forming the fin-type channel layer on the buffer layer includes epitaxially forming a channel material layer on the buffer layer, patterning the channel material layer by lithographic and etching processes to form the fin-type channel layer.

In an embodiment, the channel material layer includes InGaAs. In some embodiments, the fin-type channel layer has a thickness in the range from 10 to 500 nm.

According to the method of the present invention, because the epitaxially grown crystals have lateral crystal planes, the dislocation defect density is significantly reduced.

Thereafter, method 100 further includes forming a gate structure. Forming the gate structure comprises forming a gate insulating layer on at least a portion of the fin-type channel layer, forming a gate electrode on the gate insulating layer, and forming sidewall spacers on opposite sides of the gate electrode. The gate structure, the gate insulating layer, the gate electrode and sidewall spacers may be formed using any conventional process techniques that are known in the art, so the techniques will not be described herein for the sake of brevity.

In some embodiments, the gate insulating layer may be a high-k dielectric material such as Al₂O₃, TiSiO, and the like, and has a thickness in the range from 1 to 5 nm.

In certain embodiments, forming the gate electrode includes forming a metal gate layer on the gate insulating layer and patterning the metal gate layer by lithographic and dry etching processes. The gate electrode may be NiAu, CrAu, and any suitable material.

In some embodiments, after formation of the gate structure, the method may include performing an ion implantation onto the fin-type channel layer using the gate structure as a mask to form source and drain growth regions. Thereafter, source and drain electrodes may be formed by growing a semiconductor material on the source and drain growth regions.

In some embodiments, the fin-type channel layer is P—InGaAs, and the source/drain growth region is N+—InGaAs.

FIGS. 2 through 15 are cross-sectional views of intermediate stages in the manufacturing of a semiconductor device according to an embodiment of the present invention.

Referring to FIGS. 1 and 2, a substrate 1 is provided. Substrate 1 includes an array of cavities. Each cavity has a number of lateral sides. Each lateral side of a cavity has a lateral direction that is in line with the direction of the lateral crystal plane of the substrate. For example, the cavity has a polygonal shape or profile, e.g., a hexagonal (sigma) shape or a Σ-shape.

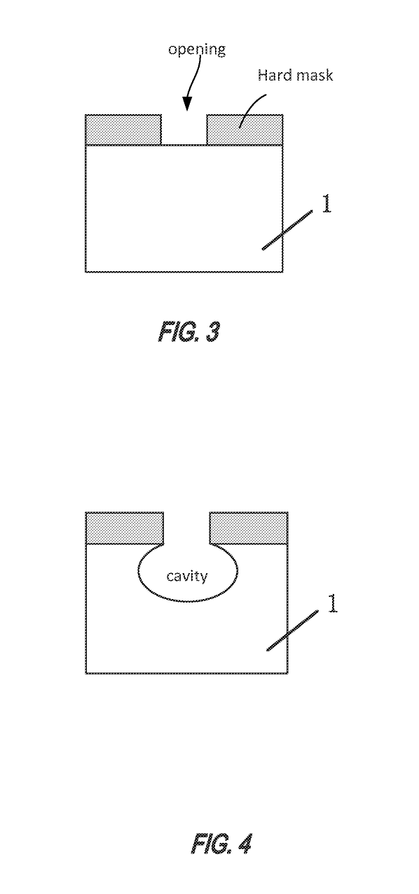

FIGS. 3 through 6 show a cavity at various stages in a fabrication process according to an exemplary embodiment of the present invention.

Referring to FIG. 3, a hard mask having an opening is formed on the substrate. In an embodiment, the hard mask can be SiO₂. For example, the hard mask can be deposited on the substrate and then etched back to have an opening exposing a surface of the substrate.

Thereafter, substrate 1 is etched through the mask opening using a suitable etchant to form a bowl-shaped cavity within substrate 100, as shown in FIG. 4. In some embodiments, etching the substrate may use HBr or Cl2 as a plasma etchant.

Thereafter, the bowl-shaped cavity is further etched in a wet etching process utilizing tetramethyl ammonium hydroxide (TMAH) as an etchant to form a cavity having a Σ-shape. The Σ-shaped cavity has a bottom portion, a middle portion and an upper portion, the mid-section is wider than the bottom portion and the top portion, as shown in FIG. 5.

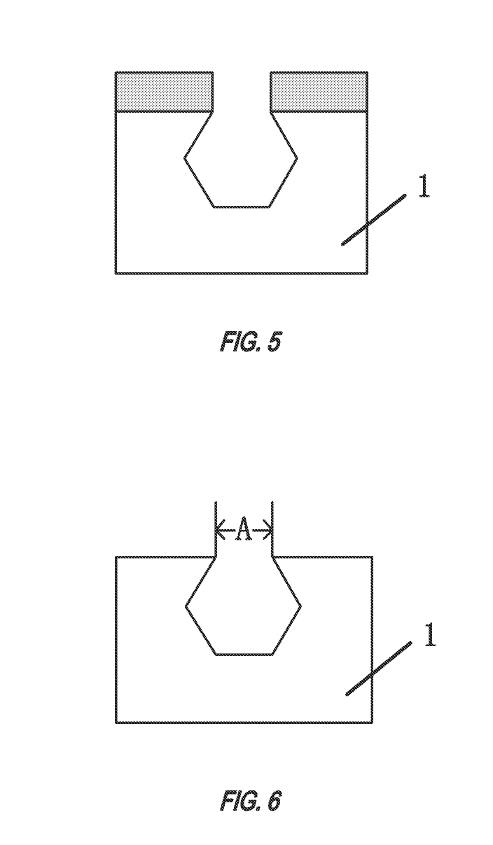

Thereafter, the hard mask is removed to complete the patterning of substrate 1, as shown in FIG. 6. In an embodiment, the Σ-shaped cavity has an opening A at the top surface of substrate 1 in a range between 5 nm and 500 nm. In some embodiments, the array of cavities in substrate 1 has a density in the range from 1 to 100 cavities/um².

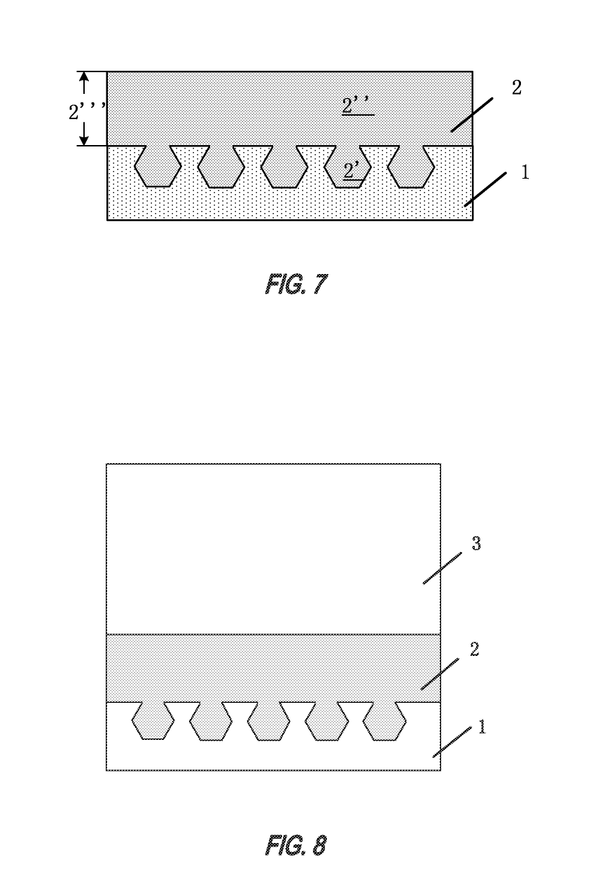

Thereafter, a buffer layer 2 is epitaxially grown within the cavities in substrate 1 to have a first portion 2′ filling the cavities and overgrown (overfilling the cavities) to have a second portion 2″ that results in a layer having a thickness 2′, as shown in FIG. 7 (Step 102). The buffer layer may be InP and the thickness 2″′ is in the range from 10 nm to 500 nm.

Thereafter, a channel layer 3 is epitaxially grown on buffer layer 2 using a metal-organic chemical vapor deposition (MOCVD), metal organic chemical vapor deposition, molecular beam epitaxy (MBE) process, and the like, as shown in FIG. 8. In some embodiments, channel layer 3 is made of InGaAs and has a thickness in the range between 10 nm and 500 nm.

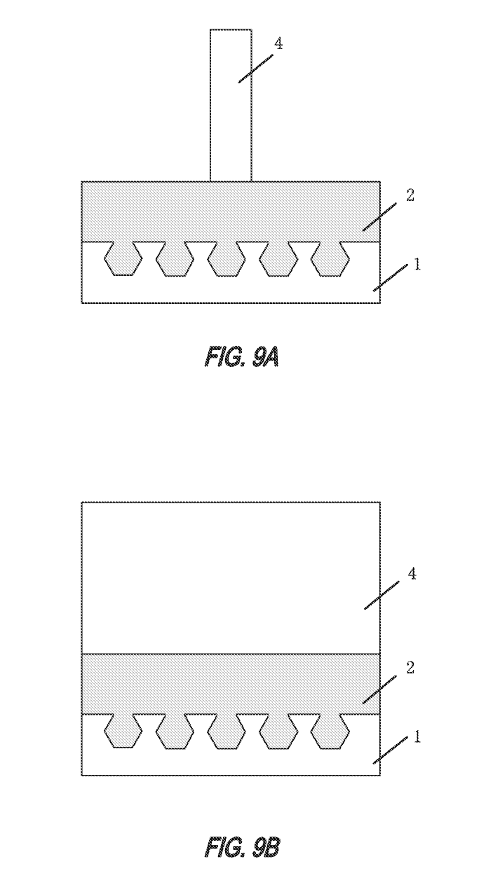

Thereafter, channel layer 3 is patterned by photolithographic and dry etching processes to form a fin-type channel layer 4 on buffer layer 2 (Step 103). FIG. 9A is a cross sectional view of the intermediate semiconductor structure taken along a perpendicular direction to the fin-type channel layer. FIG. 9B is a cross sectional view of the intermediate semiconductor structure taken along a longitudinal direction of the fin-type channel layer.

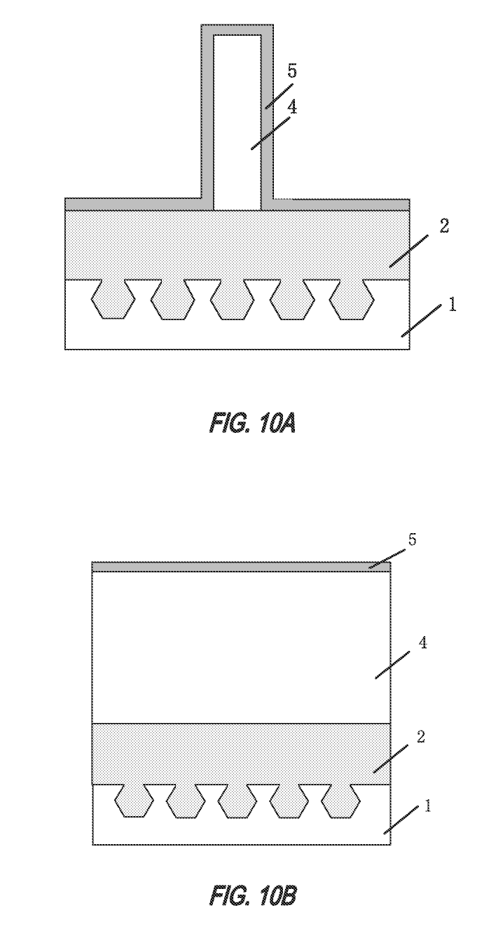

Thereafter, a gate insulating layer 5 is formed on fin-type channel layer 4. Gate insulating layer 5 covers at least a portion of fin-type channel layer 4 and at least a portion of buffer layer 2. FIG. 10A is a cross sectional view of the intermediate semiconductor structure taken along the perpendicular (traverse) direction to the fin-type channel layer. FIG. 10B is a cross sectional view of the intermediate semiconductor structure taken along the longitudinal direction of the fin-type channel layer.

In an embodiment, gate insulating layer 5 may be made of a high-k dielectric material, such as Al₂O₃, TiSOₓ, and the like. The thickness of gate insulating layer 5 can be in the range between 1 nm and 5 nm.

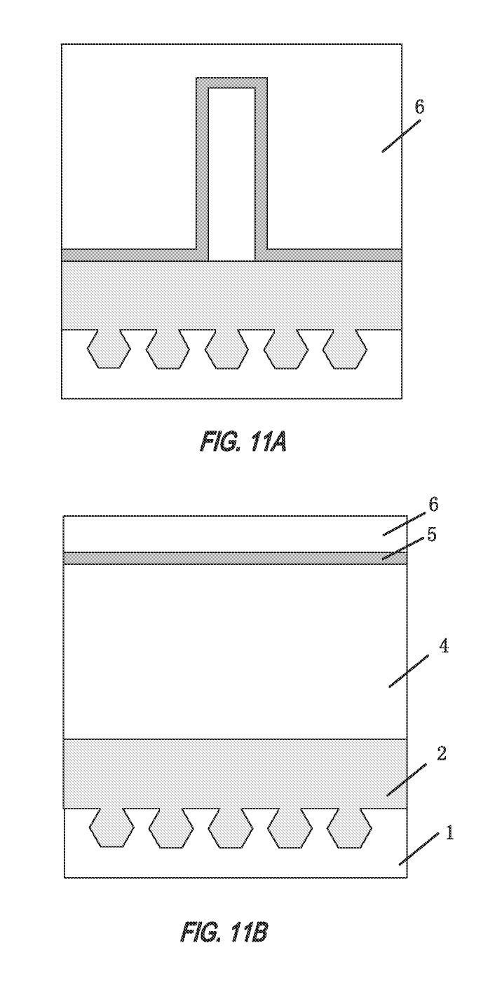

Thereafter, a gate material layer 6 is deposited on gate insulating layer 5 by metal-organic chemical vapor deposition (MOCVD), metal organic chemical vapor deposition, atomic layer deposition (ALD), molecular beam epitaxy (MBE) process, and the like. FIG. 11A is a cross sectional view of the intermediate semiconductor structure taken along the perpendicular (transverse) direction to the fin-type channel layer. FIG. 11B is a cross sectional view of the intermediate semiconductor structure taken along the longitudinal (length) direction of the fin-type channel layer. In an embodiment, gate material 6 may be a metal material, such as NiAu or CrAu.

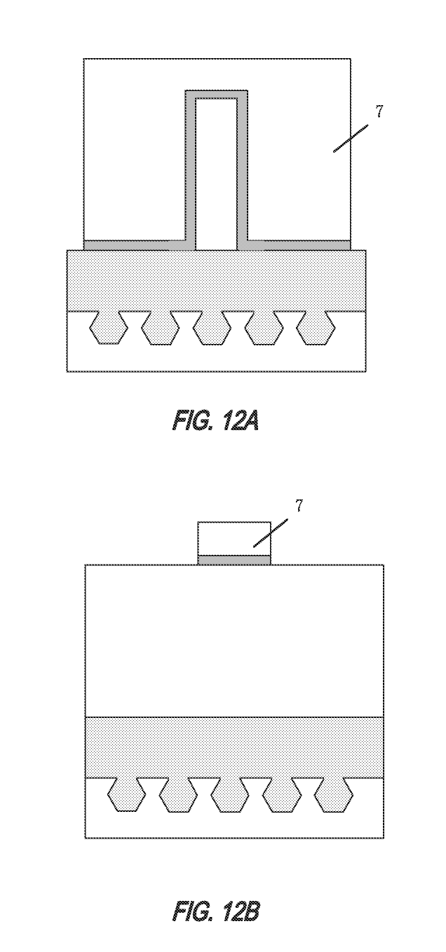

Thereafter, a gate electrode 7 is formed by patterning gate material 6. FIG. 12A is a cross sectional view of the intermediate semiconductor structure taken along the perpendicular direction to the fin-type channel layer. FIG. 12B is a cross sectional view of the intermediate semiconductor structure taken along the longitudinal direction of the fin-type channel layer.

The invention is not limited to the specific embodiments hereof. For example, in some other embodiments, the gate material may be polysilicon, the gate electrode may be a polysilicon gate or a dummy polysilicon gate. The dummy polysilicon gate may further be replaced with a metal gate in subsequent process steps.

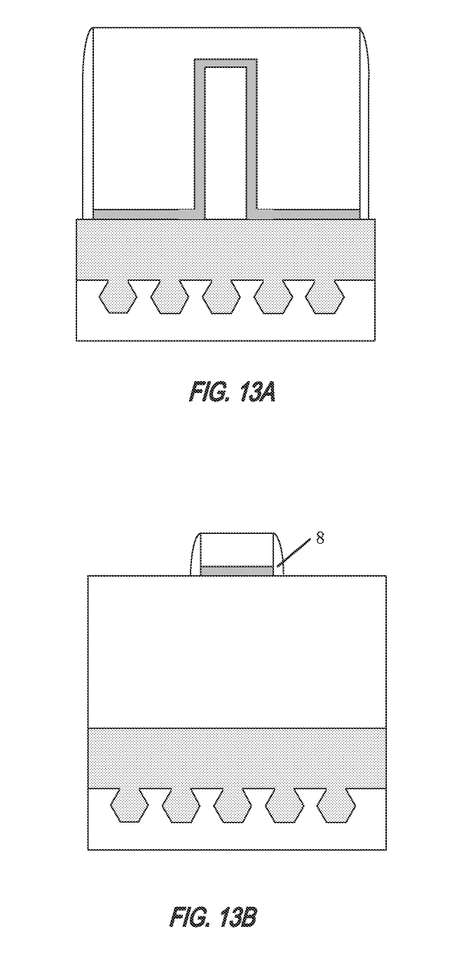

After formation of the gate electrode, sidewall spacers 8 are formed on opposite sides of gate electrode 7 to form a gate structure. FIG. 13A is a cross sectional view of the intermediate semiconductor structure taken along the perpendicular direction to the fin-type channel layer. FIG. 13B is a cross sectional view of the intermediate semiconductor structure having the gate structure taken along the longitudinal direction of the fin-type channel layer.

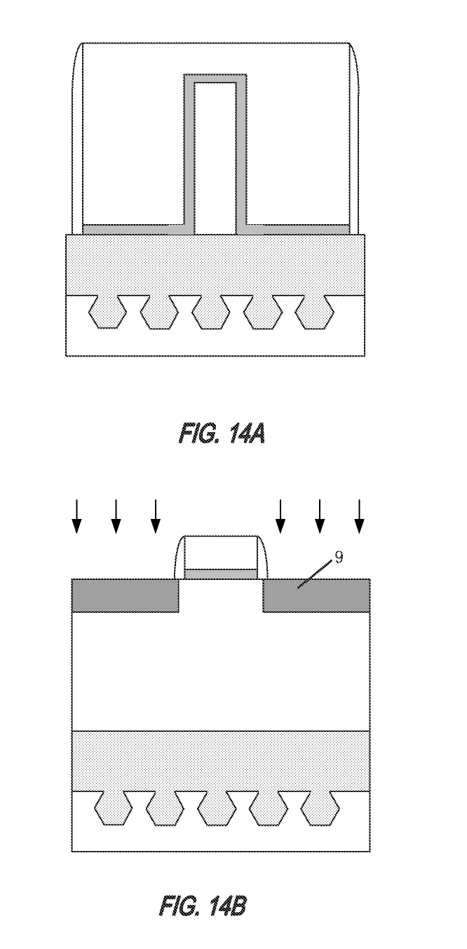

Thereafter, the fin-type channel layer 4 is subjected to ion implantation using the gate structure as a mask to form source and drain growth regions 9 on opposite ends of the fin-type channel layer. In an embodiment, source and drain growth regions 9 are formed by N-type lightly doped drain (NLDD) ion implanting following by a rapid thermal anneal (RTA) process. FIG. 14A is a cross sectional view of the intermediate semiconductor structure taken along the perpendicular direction to the fin-type channel layer. FIG. 14B is a cross sectional view illustrating the intermediate semiconductor structure having the source and drain growth regions 9 taken along the longitudinal direction of the fin-type channel layer.

In some embodiments, the fin-type channel layer is made of P—InGaAs, the source and drain growth regions are made of N+—InGaAs.

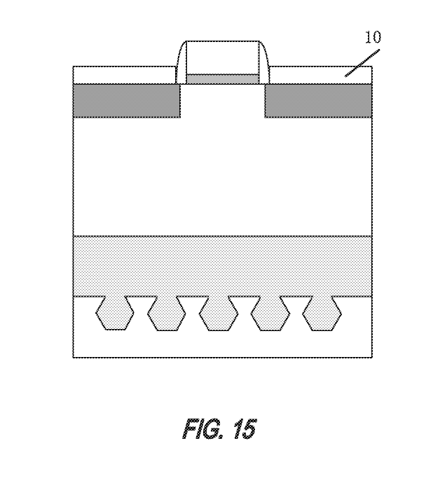

Thereafter, source and drain electrodes 10 are formed on the corresponding source and drain growth regions 9. The cross sectional view of the semiconductor device thus formed is shown in FIG. 15 taken along the perpendicular direction to the fin-type channel layer.

The invention is not limited to the specific embodiments hereof. For example, in some other embodiments, the gate material may be polysilicon, the gate electrode may be a polysilicon gate or a dummy polysilicon gate. The dummy polysilicon gate may further be replaced with a metal gate in subsequent process steps.

Embodiments of the present invention provide a semiconductor device. The semiconductor device includes a substrate having an array of cavities. Each cavity has a number of lateral sides forming a Σ-shaped profile. Each lateral side of the cavity has a lateral direction in line with the directional of the crystal plane of the substrate. The semiconductor device further includes an InP buffer layer disposed on the substrate and filling the cavities, and a fin-type channel layer disposed on the buffer layer.

The semiconductor device also includes a gate structure disposed on the fin-type channel layer. The gate structure includes a gate insulating layer disposed on at least a portion of the fin-type channel layer, a gate electrode disposed on the gate insulating layer, and sidewall spacers disposed on opposite sides of the gate electrode.

Furthermore, the semiconductor device also includes source and drain growth regions on opposite ends of the fin-type channel layer, and source and drain electrodes disposed on the corresponding source and drain growth regions.

While the present invention is described herein with reference to illustrative embodiments, this description is not intended to be construed in a limiting sense. Rather, the purpose of the illustrative embodiments is to make the spirit of the present invention be better understood by those skilled in the art. In order not to obscure the scope of the invention, many details of well-known processes and manufacturing techniques are omitted. Various modifications of the illustrative embodiments as well as other embodiments will be apparent to those of skill in the art upon reference to the description. It is therefore intended that the appended claims encompass any such modifications.

Furthermore, some of the features of the preferred embodiments of the present invention could be used to advantage without the corresponding use of other features. As such, the foregoing description should be considered as merely illustrative of the principles of the invention, and not in limitation thereof.

1. A method for manufacturing a semiconductor device comprising:
providing a substrate having an array of cavities, each of the cavities having a plurality of lateral sides, each lateral side having a lateral direction being in line with a direction of a crystal lateral plane of the substrate;
forming a buffer layer over the substrate and filling the cavities; and
forming a fin-type channel layer on the buffer layer.

2. The method of claim 1, further comprising:
forming a gate structure comprising a gate dielectric layer overlying at least a portion of the fin-type channel layer, a gate electrode overlying the gate dielectric layer, and sidewall spacers on opposite sides of the gate electrode.

3. The method of claim 2, further comprising:
performing an ion implantation onto the fin-type channel layer using the gate structure as a mask to form source and drain growth regions.

4. The method of claim 3, wherein the source and drain growth regions are made of N+—InGaAs.

5. The method of claim 1, wherein providing the substrate comprises:
patterning the substrate using a hard mask having an array of openings; and
selectively etching the substrate through the openings using a wet etching process to form the array of cavities.

6. The method of claim 1, wherein forming the fin-type channel layer comprises:
forming a channel material layer on the buffer layer; and
patterning the channel material layer to form the fin-type channel layer.

7. The method of claim 1, wherein the array of cavities has a density in a range from 1 to 100 cavities/um².

8. The method of claim 1, wherein the buffer layer is made of InP.

9. The method of claim 8, wherein the fin-type channel layer is made of P—InGaAs.

10. The method of claim 1, wherein the fin-type channel layer is made of InGaAs.

11. The method of claim 1, wherein each of the cavities has a sigma shape (Σ-shape).

12.-20. (canceled)
